(19) United States
(12) Patent Application Publication
(10) Pub. No.: US 2024/0178631 A1
(43) Pub. Date: May 30, 2024

(54) LASER DIODE AND LASER DIODE MANUFACTURING METHOD

(71) Applicant: INGENTEC CORPORATION, Miaoli County (TW)

(72) Inventors: Ai-Sen LIU, Miaoli County (TW); Hsiang-An FENG, Miaoli County (TW); Cheng-Yu CHUNG, Miaoli County (TW); Ya-Li CHEN, Miaoli County (TW)

(21) Appl. No.: 18/324,166

(22) Filed: May 26, 2023

(30) Foreign Application Priority Data
Nov. 30, 2022 (TW) 111145948

(51) Int. Cl. H01S 5/02; H01S 5/183

(52) U.S. Cl. CPC H01S 5/0206; H01S 5/18311

(57) ABSTRACT

A laser diode includes an original substrate having a substrate coefficient of thermal expansion, an epitaxy structure formed on the original substrate, and a composite multi-layer metal board disposed below the original substrate and at least including a first metal layer and a second metal layer. The first metal layer and the second metal layer are stacked, a material of the first metal layer is different from a material of the second metal layer, and the composite multi-layer metal board has a modified coefficient of thermal expansion. The original substrate has an initial thickness as the epitaxy structure is grown thereon, the original substrate is thinned to a combining thickness for attaching the composite multi-layer metal board, and the modified coefficient of thermal expansion of the composite multi-layer metal board is proximate to the substrate coefficient of thermal expansion.

### RELATED APPLICATIONS

This application claims priority to Taiwan Application Serial Number 111145948, filed Nov. 30, 2022, which is herein incorporated by reference.

### BACKGROUND

### Technical Field

The present disclosure relates to a diode and a diode manufacturing method. More particularly, the present disclosure relates to a laser diode which may emit lights and a laser diode manufacturing method.

### Description of Related Art

Laser diodes are made by semiconductors, the epitaxy structure thereof includes two distributed bragg reflectors (DBR), and therefore an optical resonant cavity can be formed to reflect the photons. The laser diodes have an advantage of high effect compared to other light emitting diodes.

Since the epitaxy structure may generate such a huge amount of heat as the laser diode is working, the heat may transmit to the original substrate below the epitaxy structure, and because the original substrate is generally made of GaAs having lower heat transmission coefficient, the poor heat dissipation becomes a problem.

Hence, how to improve the structure of the laser diode to solve the aforementioned problem becomes a target that those in the industry pursue.

### SUMMARY

According to one aspect of the present disclosure, a laser diode includes an original substrate having a substrate coefficient of thermal expansion, an epitaxy structure formed on the original substrate, and a composite multi-layer metal board disposed below the original substrate and at least including a first metal layer and a second metal layer. The first metal layer and the second metal layer are stacked, a material of the first metal layer is different from a material of the second metal layer, and the composite multi-layer metal board has a modified coefficient of thermal expansion. The original substrate has an initial thickness as the epitaxy structure is grown thereon, the original substrate is thinned to a combining thickness for attaching the composite multi-layer metal board, and the modified coefficient of thermal expansion of the composite multi-layer metal board is proximate to the substrate coefficient of thermal expansion.

According to another aspect of the present disclosure, a laser diode manufacturing method includes an epitaxy structure growing step, an original substrate thinning step, and a composite multi-layer metal board attaching step. In the epitaxy structure growing step, an epitaxy structure is formed on an original substrate, and the original substrate has an initial thickness. In the original substrate thinning step, a thinning process is performed to allow the original substrate to be thinned to a combining thickness. In the composite multi-layer metal board attaching step, a composite multi-layer metal board is disposed below the original substrate, the composite multi-layer metal board at least includes a first metal layer and a second metal layer, and the first metal layer is located between the original substrate and the second metal layer.

### BRIEF DESCRIPTION OF THE DRAWINGS

The disclosure can be more fully understood by reading the following detailed description of the embodiments, with reference made to the accompanying drawings as follows:

FIG. 1 shows a front view of a laser diode according to a first embodiment of the present disclosure.

FIG. 2 shows a three-dimensional schematic view of a laser diode according to a second embodiment of the present disclosure.

FIG. 3 shows a block flow chart of a laser diode manufacturing method according to a third embodiment of the present disclosure.

FIG. 4 shows a process flow of the laser diode manufacturing method of the third embodiment of FIG. 3.

FIG. 5 shows a top view of a laser diode manufactured by the laser diode manufacturing method of the third embodiment of FIG. 3.

### DETAILED DESCRIPTION

It will be understood that when an element (or mechanism or module) is referred to as being “disposed on”, “connected to” or “coupled to” another element, it can be directly disposed on, connected or coupled to the other element, or intervening elements may also be present. In contrast, when an element is referred to as being “directly disposed on”, “directly connected to” or “directly coupled to” another element, there are no intervening elements present.

In addition, the terms first, second, third, etc. are used herein to describe various elements or components, these elements or components should not be limited by these terms. Consequently, a first element or component discussed below could be termed a second element or component.

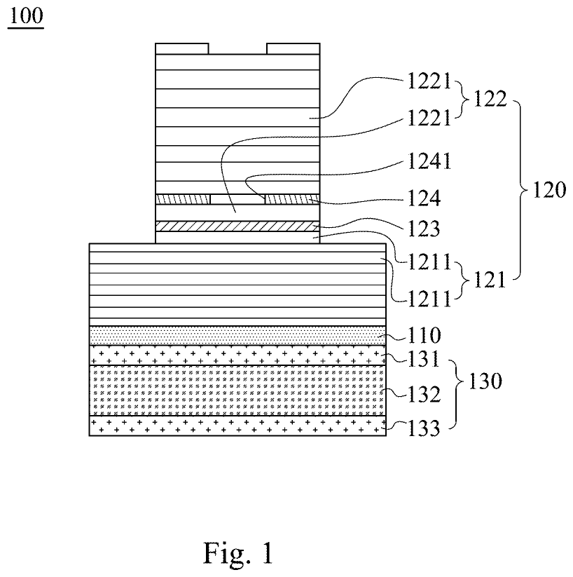

FIG. 1 shows a front view of a laser diode 100 according to a first embodiment of the present disclosure. As shown in FIG. 1, a laser diode 100 includes an original substrate 110 having a substrate coefficient of thermal expansion, an epitaxy structure 120 formed on the original substrate 110, and a composite multi-layer metal board 130 disposed below the original substrate 110 and at least including a first metal layer 131 and a second metal layer 132. The first metal layer 131 and the second metal layer 132 are stacked, a material of the first metal layer 131 is different from a material of the second metal layer 132, and the composite multi-layer metal board 130 has a modified coefficient of thermal expansion. The original substrate 110 has an initial thickness as the epitaxy structure 120 is grown thereon, the original substrate 110 is thinned to a combining thickness for attaching the composite multi-layer metal board 130, and the modified coefficient of thermal expansion of the composite multi-layer metal board 130 is proximate to the substrate coefficient of thermal expansion.

Therefore, the composite multi-layer metal board 130 assists the heat dissipation capability of the laser diode 100. Moreover, since the original substrate 110 is thinned, a perpendicular heat conduction distance is shortened, and the time that the heat transforms to the composite multi-layer metal board 130 can be shortened. In addition, because the composite multi-layer metal board 130 includes the first metal layer 131 and the second metal layer 132 made of different materials, the modified coefficient of thermal expansion can be adjusted to get close to the substrate coefficient of thermal expansion via controlling the thicknesses of the first metal layer 131 and the second metal layer 132, thereby preventing the composite multi-layer metal board 130 and the original substrate 110 from separating from each other after assembling owing to the large difference of the coefficient of thermal expansion. Furthermore, with assembling the composite multi-layer metal board 130, the light output efficiency can be increased, especially the light output and light conversion effect. The details of the laser diode 100 may be described hereinafter.

The laser diode 100 of the first embodiment may have a vertical-cavity surface-emitting laser (VCSEL) diode structure. Hence, the epitaxy structure 120 may include a first reflector 121 disposed above the original substrate 110, an active layer 123 disposed above the first reflector 121, and a second reflector 122 disposed above the active layer 123.

The first reflector 121 may be formed by stacking a plurality of N-type reflecting layers 1211, the material thereof may be an N-type semiconductor made by adding N-type dopants. The active layer 123 may be made of quantum wells. The second reflector 122 may be formed by stacking a plurality of P-type reflecting layers 1221, the material thereof may be a P-type semiconductor made by adding P-type dopants, and a number of the P-type reflecting layers 1221 is larger than a number of the N-type reflecting layers 1211. Additionally, the epitaxy structure 120 may further include an oxidized portion 124, and the oxidized portion 124 is located in the second reflector 122 and includes an inner edge 1241. Because the epitaxy structure 120 of the laser diode 100 is conventional and is not a key improving feature of the present disclosure, the details will not be repeated. In other embodiments, the epitaxy structure may not be limited to the above.

A material of the original substrate 110 is GaAs, the substrate coefficient of thermal expansion may be equal to 5.73 ppm/K, and a heat transfer coefficient may be equal to 52 W/mK. The epitaxy structure 120 may have an epitaxy coefficient of thermal expansion being ranged between 5.5 ppm/K to 5.8 ppm/K, and therefore the substrate coefficient of thermal expansion is proximate to the epitaxy coefficient of thermal expansion. The original substrate 110 may have an initial thickness, e.g., 430 μm, and is configured for the first reflector 121, the active layer 123 and the second reflector 122 to grow thereon sequentially. Subsequently, the original substrate 110 may be thinned, for example by grinding, to allow the initial thickness to be thinned to the combining thickness, e.g., 150 μm, and may be combined with the composite multi-layer metal board 130. The combining thickness may be equal to 120 μm in one embodiment, and may be equal to 100 μm in another embodiment, but the present disclosure is not limited thereto. In addition, as the combining thickness is thinner, the light output and light conversion effect is increased.

The composite multi-layer metal board 130 may further include a third metal layer 133, the second metal layer 132 is disposed between the first metal layer 131 and the third metal layer 133, and the material of the first metal layer 131 is identical to a material of the third metal layer 133. The material of the first metal layer 131 and the material of the third metal layer 133 may for example be copper, the material of the second metal layer 132 may for example be nickel-iron alloy, but the materials should not be limited thereto.

In addition, a thickness of the first metal layer 131 and a thickness of the third metal layer 133 are smaller than a thickness of the second metal layer 132. A thickness ratio of the first metal layer 131, the second metal layer 132 and the third metal layer 133 may be ranged between 1:3:1 to 1:9:1. Therefore, different modified coefficient of thermal expansion may be adjusted to cooperate with different original substrate 110. For example, the modified coefficient of thermal expansion of the composite multi-layer metal board 130 may be ranged between 5.8 ppm/K to 6.0 ppm/K, and a difference between the modified coefficient of thermal expansion and the substrate coefficient of thermal expansion is about 5%. The heat transfer coefficient of the composite multi-layer metal board 130 may be about 180 W/mK to increase heat dissipation, and a thermal resistance of the laser diode 100 may be 20% lower than a conventional laser diode. Moreover, a resistivity of the composite multi-layer metal board 130 may be equal to 10⁻¹¹ MΩ·cm, and a resistivity of the original substrate 110 made of GaAs is range between 0.01 MΩ·cm to 100 MΩ·cm. Consequently, as the original substrate 110 is thinned and adhered to the composite multi-layer metal board 130, the whole resistance of the laser diode 100 may be decrease, and the current density may be increased to increase the light output efficiently. Furthermore, the Young's modulus of the composite multi-layer metal board 130 is equal to 130 Gpa, the Young's modulus of the original substrate 110 made of GaAs is 83 Gpa, and support of the epitaxy structure 120 can be reinforced via the composite multi-layer metal board 130.

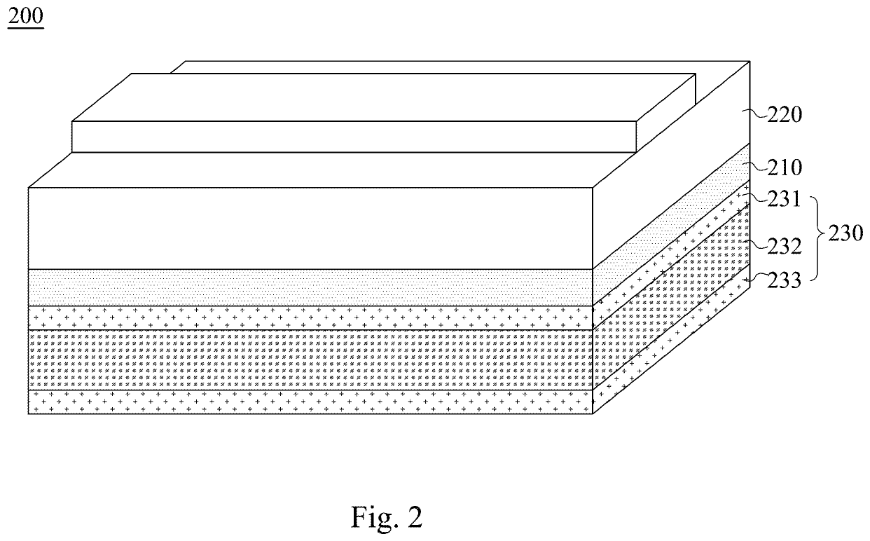

FIG. 2 shows a three-dimensional schematic view of a laser diode 200 according to a second embodiment of the present disclosure. The laser diode 200 may also include an original substrate 210, an epitaxy structure 220 and a composite multi-layer metal board 230. The composite multi-layer metal board 230 may also include a first metal layer 231, a second metal layer 232 and a third metal layer 233. The difference between the laser diode 200 and the laser diode 100 of the first embodiment is that the laser diode 200 may have an edge emitting laser (EEL) diode structure. Hence, the epitaxy structure 220 may for example include an N-type buffer layer, an N-cladding layer, a lower separated confinement hetero-structure (SCH), an active layer, an upper separated confinement hetero-structure, a P-cladding layer, and a contact, and the epitaxy structure 220 may have a ridge structure. Additionally, the original substrate 210 of the second embodiment may be made of InP. With the modification of the thicknesses of the first metal layer 231, the second metal layer 232 and the third metal layer 233, the modified coefficient of thermal expansion of the composite multi-layer metal board 230 is proximate to the substrate coefficient of thermal expansion.

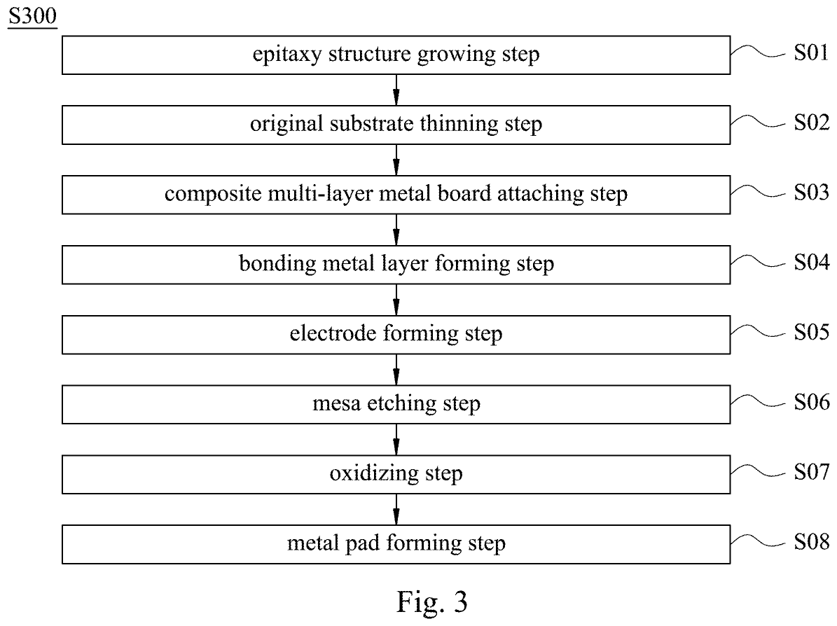

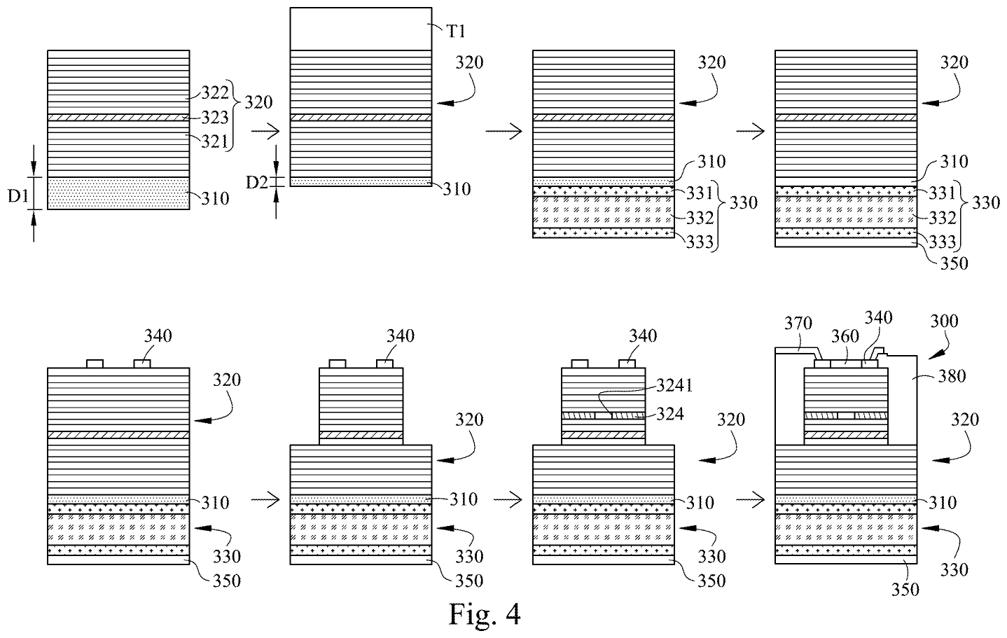

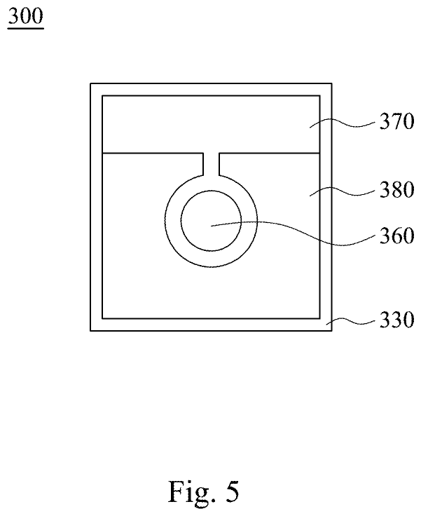

FIG. 3 shows a block flow chart of a laser diode manufacturing method S300 according to a third embodiment of the present disclosure. FIG. 4 shows a process flow of the laser diode manufacturing method S300 of the third embodiment of FIG. 3. FIG. 5 shows a top view of a laser diode 300 manufactured by the laser diode manufacturing method S300 of the third embodiment of FIG. 3. The laser diode manufacturing method S300 includes an epitaxy structure growing step S01, an original substrate thinning step S02, and a composite multi-layer metal board 330 attaching step S03.

In the epitaxy structure growing step S01, an epitaxy structure 320 is formed on an original substrate 310, and the original substrate 310 has an initial thickness D1.

In the original substrate thinning step S02, a thinning process is performed to allow the original substrate 310 to be thinned to a combining thickness D2.

In the composite multi-layer metal board attaching step S03, a composite multi-layer metal board 330 is disposed below the original substrate 310, the composite multi-layer metal board 330 at least includes a first metal layer 331 and a second metal layer 332, and the first metal layer 331 is located between the original substrate 310 and the second metal layer 332.

Therefore, as the original substrate 310 is attached to the composite multi-layer metal board 330 after thinning, the lighting characteristics and the heat dissipation capability of the laser diode 300 may be increased.

The laser diode manufacturing method S300 may further include a mesa etching step S06 and an oxidizing step S07. In the mesa etching step S06, a portion of the epitaxy structure 320 is removed. In the oxidizing step S07, the epitaxy structure 320 includes a first reflector 321, an active layer 323 and a second reflector 322 stacked in order above the original substrate 310, an oxidizing process is performed on the second reflector 322 to form an oxidized portion 324, and the oxidized portion 324 is hollow and has an inner edge 3241.

As shown in FIG. 3 and FIG. 4, beginning with the epitaxy structure growing step S01 to grow the epitaxy structure 320 on the original substrate 310, and because the original substrate 310 is not thinned at this time, the initial thickness D1 is larger than the combining thickness D2. Subsequently, performing the original substrate thinning step S02, a temporary substrate T1 is attached onto the epitaxy structure 320, and the thinning process is performed by grinding. With the configuration of the temporary substrate T1, the grinding machine may clamp the temporary substrate T1 but not the epitaxy structure 320, thereby avoiding damage of the epitaxy structure 320.

Latter, the composite multi-layer metal board attaching step S03 can be performed. In addition to attach the composite multi-layer metal board 330 below the original substrate 310, the temporary substrate T1 may also be removed. The composite multi-layer metal board 330 may include a first metal layer 331, a second metal layer 332 and a third metal layer 333 stacked sequentially as the first embodiment. The first metal layer 331, the second metal layer 332 and the third metal layer 333 may be modified in advance to allow the modified coefficient of thermal expansion of the composite multi-layer metal board 330 to be proximate to the substrate coefficient of thermal expansion of the original substrate 310.

The laser diode manufacturing method S300 may further include a bonding metal layer forming step S04 and an electrode forming step S05 preformed after the composite multi-layer metal board attaching step S03. The bonding metal layer forming step S04 is to form a bonding metal layer 350 below the composite multi-layer metal board 330 for the latter bonding. The electrode forming step S05 is to allow a P-type metal layer 340 to be disposed above the second reflector 322, and the P-type metal layer 340 may be hollow. Subsequently, the mesa etching step S06 may be performed to etch a part of the first reflector 321, the active layer 323 and the second reflector 322 to form the mesa. After which the oxidizing step S07 may be performed to form the oxidized portion 324 in the second reflector 322. In other embodiments, the bonding metal layer forming step may be omitted and no bonding metal layer is formed.

The laser diode manufacturing method S300 may further include a metal pad forming step S08. A protecting layer 380 with extinction, which may be made of Polyphenylene Oxide (PPO), may be formed. And then a metal pad 370 may be formed thereon, and the metal pad 370 is connected to the P-type metal layer 340. The hollow portion of the P-type metal layer 340 may be filled by a silicon nitride layer 360, and the laser diode 300 can be formed as shown in FIG. 5.

It may be known from the above, the laser diode of the present disclosure has good characteristics. With remaining the original substrate, no other etching stop layer such as AIAs has to be contained between the epitaxy structure and the original substrate. Therefore, the current crowding effect (CCE) occurred by the high resistance of AIAs may be avoided, and the problem that the coefficient of thermal expansion of AIAs does not match the modified coefficient of thermal expansion of the composite multi-layer metal board may also avoided.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A laser diode, comprising:
an original substrate having a substrate coefficient of thermal expansion;
an epitaxy structure formed on the original substrate; and
a composite multi-layer metal board disposed below the original substrate and at least comprising a first metal layer and a second metal layer, wherein the first metal layer and the second metal layer are stacked, a material of the first metal layer is different from a material of the second metal layer, and the composite multi-layer metal board has a modified coefficient of thermal expansion;
wherein the original substrate has an initial thickness as the epitaxy structure is grown thereon, the original substrate is thinned to a combining thickness for attaching the composite multi-layer metal board, and the modified coefficient of thermal expansion of the composite multi-layer metal board is proximate to the substrate coefficient of thermal expansion.

2. The laser diode of claim 1, wherein the laser diode has a vertical-cavity surface-emitting laser diode structure.

3. The laser diode of claim 2, wherein a material of the original substrate is GaAs, the epitaxy structure has an epitaxy coefficient of thermal expansion, and the substrate coefficient of thermal expansion is proximate to the epitaxy coefficient of thermal expansion.

4. The laser diode of claim 2, wherein the epitaxy structure comprises:
a first reflector disposed above the original substrate;
an active layer disposed above the first reflector; and
a second reflector disposed above the active layer.

5. The laser diode of claim 4, wherein the first reflector is formed by stacking a plurality of N-type reflecting layers, the second reflector is formed by stacking a plurality of P-type reflecting layers, and a number of the P-type reflecting layers is larger than a number of the N-type reflecting layers.

6. The laser diode of claim 1, wherein the laser diode has an edge emitting laser diode structure.

7. The laser diode of claim 1, wherein the composite multi-layer metal board further comprises a third metal layer, the second metal layer is disposed between the first metal layer and the third metal layer, and the material of the first metal layer is identical to a material of the third metal layer.

8. The laser diode of claim 7, wherein a thickness of the first metal layer and a thickness of the third metal layer are smaller than a thickness of the second metal layer.

9. The laser diode of claim 7, wherein the material of the first metal layer and the material of the third metal layer are copper, and the material of the second metal layer is nickel-iron alloy.

10. A laser diode manufacturing method, comprising:
an epitaxy structure growing step, wherein an epitaxy structure is formed on an original substrate, and the original substrate has an initial thickness;
an original substrate thinning step, wherein a thinning process is performed to allow the original substrate to be thinned to a combining thickness; and
a composite multi-layer metal board attaching step, wherein a composite multi-layer metal board is disposed below the original substrate, the composite multi-layer metal board at least comprises a first metal layer and a second metal layer, and the first metal layer is located between the original substrate and the second metal layer.

11. The laser diode manufacturing method of claim 10, further comprising:
a mesa etching step, wherein a portion of the epitaxy structure is removed; and
an oxidizing step, wherein the epitaxy structure comprises a first reflector, an active layer and a second reflector stacked in order above the original substrate, an oxidizing process is performed on the second reflector to form an oxidized portion, and the oxidized portion is hollow and has an inner edge.

12. The laser diode manufacturing method of claim 11, wherein, in the original substrate thinning step, a temporary substrate is attached onto the epitaxy structure, and the thinning process is performed by grinding.

13. The laser diode manufacturing method of claim 12, wherein, in the composite multi-layer metal board attaching step, the temporary substrate is removed.

14. The laser diode manufacturing method of claim 13, further comprising:
an electrode forming step, wherein a P-type metal layer is disposed above the second reflector;
wherein the electrode forming step is preformed after the composite multi-layer metal board attaching step.

15. The laser diode manufacturing method of claim 14, further comprising:
a metal pad forming step, wherein a metal pad connecting the P-type metal layer is formed.
